(19) United States
(12) Patent Application Publication
(10) Pub. No.: US 2026/0030693 A1
(43) Pub. Date: Jan. 29, 2026

(54) ENERGY ALLOCATION METHOD AND COMPUTING APPARATUS

(71) Applicant: Wistron Corporation, New Taipei City (TW)

(72) Inventors: Chun-Hsien Li, New Taipei City (TW); Chia-Chiung Liu, New Taipei City (TW)

(73) Assignee: Wistron Corporation, New Taipei City (TW)

(21) Appl. No.: 18/902,857

(22) Filed: Sep. 30, 2024

(30) Foreign Application Priority Data
Jul. 29, 2024 (TW) 113128114

(51) Int. Cl. G06Q 50/06; G01R 21/133

(52) U.S. Cl. CPC G06Q 50/06; G01R 21/133

(57) ABSTRACT

Disclosed is an energy allocation method and a computing apparatus. In the method, a historical electricity consumption of a target energy is obtained. A past period includes sub-periods, and the historical electricity consumption includes secondary electricity consumptions in sub-periods. An electricity distribution corresponding to the secondary electricity consumption in the sub-period is determined. The electricity distribution is an estimated electricity consumption distribution in sub-periods based on the electricity consumption in the sub-period. A recommended proportion of the target energy is determined according to a usage difference between the historical electricity consumption and the electricity distribution. The usage difference is a difference between the historical electricity consumption and an estimated sum. The estimated sum is a sum of estimated electricity consumptions in sub-periods under the electricity distribution, and the recommended proportion is a proportion of a recommended amount of the target energy to an electricity consumption of all energy.

### CROSS-REFERENCE TO RELATED APPLICATION

This application claims the priority benefit of Taiwan application serial no. 113128114, filed on Jul. 29, 2024. The entirety of the above-mentioned patent application is hereby incorporated by reference herein and made a part of this specification.

### BACKGROUND

### Technical Field

The disclosure relates to an energy management technology, and in particular to an energy allocation method and a computing device.

### Description of Related Art

In recent years, energy conservation and carbon reduction have become popular topics, motivating enterprises to lay out carbon reduction strategies in advance. In addition to familiarizing themselves with the process, rules and restrictions of purchasing renewable energy, it is also necessary to first assess the overall cost of carbon reduction and electricity consumption targets so as to benefit the overall operation of the enterprise and achieve carbon neutrality goals.

Regarding the control of the amount of energy transfer, the current method mainly relies on experts to perform assessments according to past experience and different types of power generation. However, this method is easily affected by fluctuations in power generation performance. As a result, enterprises can only know the transfer status for each time period in each month after receiving the bill, making it more challenging to optimize overall usage efficiency (for example, all transferred energy can be used up without generating residual electricity).

### SUMMARY

The disclosure provides an energy allocation method and a computing apparatus to suggest appropriate energy allocation and achieve energy conservation and carbon reduction.

The energy allocation method in the embodiments of the disclosure may be realized by a processor. The energy allocation method includes the following steps. A historical electricity consumption of a target energy is obtained. The historical electricity consumption is a statistical amount of the target energy used in a past period, and the past period includes multiple sub-periods. The historical electricity consumption includes multiple secondary electricity consumptions in the sub-periods. An electricity distribution of the secondary electricity consumption corresponding to one of the sub-periods is determined. The electricity distribution is a distribution of multiple estimated electricity consumptions in the sub-periods formed based on the secondary electricity consumption in the sub-period. A recommended proportion of the target energy is determined according to a usage difference between the historical electricity consumption and the electricity distribution. The usage difference is a difference between the historical electricity consumption and an estimated sum. The estimated sum is a sum of the plurality of estimated electricity consumptions in the plurality of sub-periods under the electricity distribution. The recommended proportion is a proportion of a recommended amount of the target energy to an electricity consumption of all energy.

A computing apparatus in the embodiments of the disclosure includes a storage and a processor. The storage stores a program code. The processor is coupled to the storage, loads the program code, and executes the following steps. A historical electricity consumption of a target energy is obtained. The historical electricity consumption is a statistical amount of the target energy used in a past period, and the past period includes multiple sub-periods. The historical electricity consumption includes multiple secondary electricity consumptions in the sub-periods. An electricity distribution of the secondary electricity consumption corresponding to one of the sub-periods is determined. The electricity distribution is a distribution of multiple estimated electricity consumptions in the sub-periods formed based on the secondary electricity consumption in the sub-period. A recommended proportion of the target energy is determined according to a usage difference between the historical electricity consumption and the electricity distribution. The usage difference is a difference between the historical electricity consumption and an estimated sum. The estimated sum is a sum of the plurality of estimated electricity consumptions in the plurality of sub-periods under the electricity distribution. The recommended proportion is a proportion of a recommended amount of the target energy to an electricity consumption of all energy.

Based on the above, through the energy allocation method and the computing apparatus in the embodiments of the disclosure, the electricity distribution in multiple sub-periods can be estimated, and the recommended proportion corresponding to the electricity distribution is determined. Accordingly, the efficiency of energy decision-making is improved, hence better meeting energy conservation requirements.

To make the features and advantages of the disclosure more comprehensible, several embodiments accompanied with drawings are described in detail as follows.

### BRIEF DESCRIPTION OF THE DRAWINGS

FIG. 1 is an element block diagram of a computing device according to an embodiment of the disclosure.

FIG. 2 is a flowchart of an energy allocation method according to an embodiment of the disclosure.

FIG. 3 is a flowchart illustrating the determination of historical electricity consumption according to an embodiment of the disclosure.

FIG. 4 is a flowchart illustrating the determination of future total electricity according to an embodiment of the disclosure.

FIG. 5A and FIG. 5B are schematic diagrams illustrating historical electricity consumption and electricity distribution according to an embodiment of the disclosure.

FIG. 6A and FIG. 6B are schematic diagrams illustrating historical electricity consumption and electricity distribution according to an embodiment of the disclosure.

FIG. 7A and FIG. 7B are schematic diagrams illustrating historical electricity consumption and electricity distribution according to an embodiment of the disclosure.

### DESCRIPTION OF THE EMBODIMENTS

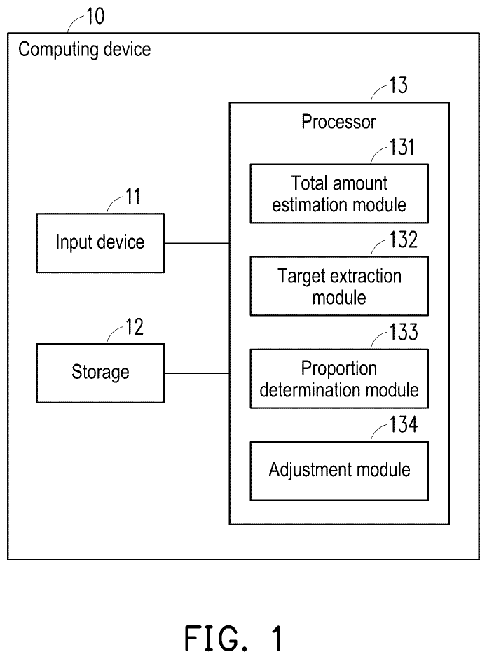

FIG. 1 is an element block diagram of a computing device 10 according to an embodiment of the disclosure. Referring to FIG. 1, the computing device 10 includes (but is not limited to) an input device 11, a storage 12, and a processor 13. The computing device 10 may be a mobile phone, tablet computer, laptop computer, desktop computer, server, voice assistant device, smart home appliance, wearable device, vehicle-mounted system, or other electronic device.

The input device 11 may be a keyboard, mouse, touch panel, or other device for inputting user operations (for example, clicking, sliding, or dragging operations). Alternatively, the input device 11 may be, for example, a communication transceiver circuit supporting Bluetooth, Wi-Fi, mobile network, optical fiber network, or other communication technologies, or, for example, a transmission interface supporting USB, UART, or Thunderbolt, thereby receiving data from other devices or transmitting data to other devices.

The storage 12 may be any type of fixed or removable random access memory (RAM), read only memory (ROM), flash memory, hard disk drive (HDD), solid-state drive (SSD), or similar element. In an embodiment, the storage 12 is used to store program codes, software modules, configurations, data (for example, text data, statistical amount, recommended amount, or differences), or files, which will be described in detail in the embodiment later.

The processor 13 is coupled to the input device 11 and the storage 12. The processor 13 may be a central processing unit (CPU), graphic processing unit (GPU), or other programmable general-purpose or special-purpose microprocessor, digital signal processor (DSP), programmable controller, field programmable gate array (FPGA), application-specific integrated circuit (ASIC), neural network accelerator, or other similar element or combination of the above elements. In an embodiment, the processor 13 is used to execute all or part of the operations of the computing device 10, and may load and execute various program codes, software modules, files, and data stored in the storage 12.

In an embodiment, the storage 12 stores program codes of a total amount estimation module 131, a target extraction module 132, a proportion determination module 133, and an adjustment module 134, and the processor 13 may load the program codes of these modules from the storage 12 and execute the processes of the method in the embodiments of the disclosure (which will be described in detail later).

In the following, the method in the embodiments of the disclosure will be described in conjunction with various devices, elements, and modules in the computing device 10. Each process of the method may be adjusted according to the implementation status and is not limited thereto.

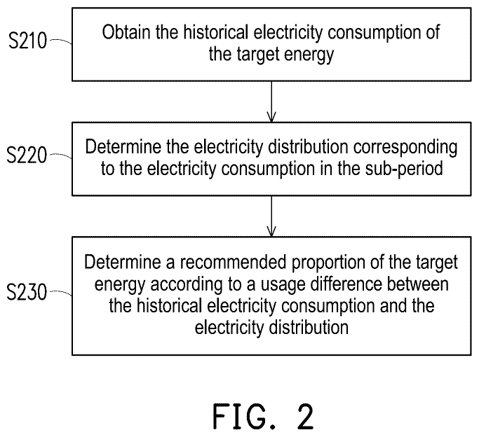

FIG. 2 is a flowchart of an energy allocation method according to an embodiment of the disclosure. Referring to FIG. 2, the processor 13 obtains the historical electricity consumption of the target energy through the target extraction module 132 (Step S210). Specifically, the target energy may be, for example, solar energy, wind energy, hydroelectric energy, or other renewable energy/green electricity. In an embodiment, the supply channels of the target energy may be limited, for example, to transfer, direct supply, certificates, or self-construction. All energy includes the target energy and other energy. Compared to renewable energy (which serves as the target energy), other energy may be thermal energy or nuclear energy. However, according to different requirements in design, the type of the target energy may be changed, and the embodiments of the disclosure do not impose limitations.

The historical electricity consumption is a statistical amount of the target energy used during a past period. The electricity consumption may be limited to specific geographic/administrative regions, buildings, and/or units. For example, the electricity consumption of an automobile factory in a certain region. The electricity consumption may be limited to specific time intervals. For example, a year, half a year, or two weeks. The past period is a period of time before the current time. For example, if the current time is June 2024, then the past period may be January to December 2021, January to December 2022, January to December 2023, January to May 2024, etc. The past period includes multiple sub-periods. For example, January to December 2021 has a total of 12 sub-periods, and each sub-period is a month. Another example is that the sub-period may be a peak time period, semi-peak time period, or off-peak time period, and its time range may be adjusted according to actual requirements.

The statistical amount of the target energy use is the electricity consumption of the target energy during the period. The historical electricity consumption includes multiple secondary electricity consumptions in multiple sub-periods. The secondary electricity consumption is the electricity consumption of the corresponding energy during the sub-period.

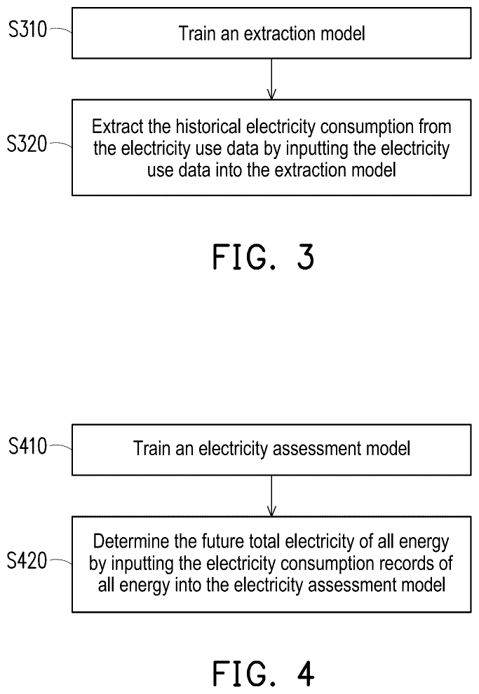

FIG. 3 is a flowchart illustrating the determination of historical electricity consumption according to an embodiment of the disclosure. Referring to FIG. 3, the target extraction module 132 may train an extraction model (Step S310). Specifically, the extraction model is trained through a machine learning algorithm. The extraction model is trained to understand the correlation between electricity use data and electricity consumption. Electricity use data is data that records electricity consumption related to the target energy. For example, bills from the power company. The standard data may be in text form/format, voice form, image form, or other forms. The machine learning algorithm may be, for example, support vector regression (SVR), convolutional neural network (CNN), recurrent neural networks (RNN), multilayer perceptron, generative adversarial network (GAN), or other algorithm. The machine learning algorithm can analyze labeled samples (for example, standard samples of determined electricity consumption) to establish the correlation between electricity use data (i.e., the input of the model) and historical electricity consumption (i.e., the output of the model). The extraction model is the model constructed after learning, and can be used to infer from data to be assessed (for example, the electricity use data to be assessed) to identify the historical electricity consumption recorded in the electricity use data.

In an embodiment, the electricity use data is in text form, and the machine learning algorithm includes a natural language processing algorithm. The natural language processing (NLP) algorithm may be, for example, a Dual-Level Collaborative Transformer (DLCT), GPT (generative pre-training) or BERT (Bidirectional Encoder Representation from Transformer), but is not limited thereto. Through NLP, it may be attempted to find interactions between computers and human languages, and further process and analyze a large amount of natural language data. In an embodiment, the extraction model trained by the NLP algorithm can understand the text content of the electricity use data, and may be used to extract content about historical electricity consumption from the text content.

In an embodiment, the target extraction module 132 may convert electricity use data in image or voice form into text form, and then input the data into the extraction model trained by the NLP algorithm. For example, the input device 11 obtains an image of a bill from the power company. The target extraction module 132 may use image-to-text technology (for example, optical character recognition (OCR)) to extract the bill text:
Row 1 Customer No. Payment Deadline
Row 2 AAA-BBB
. . .
Row 14 Semi-peak (non-summer month) demand 1888 Total amount payable $1,111,126
. . .
Row 25 Power factor (%) 95
   The target extraction module 132 inputs this bill text into a natural language model (for example, GPT). Taking the semi-peak consumption in kWh for example (i.e., the sub-period is the semi-peak time period), the question “Please extract and simplify the summary content recording the values regarding ‘billed semi-peak kWh’ from the bill text” is input, and the result is as follows:
From the provided customer members and bill text thereof, the summary content related to “billed semi-peak kWh” is extracted:
Semi-peak (non-summer month) demand: 1888
   Similarly, “billed semi-peak kWh” may be replaced with other periods or time periods, and the historical electricity consumption in the corresponding period or time period may be obtained accordingly.

In an embodiment, the NLP algorithm may be combined with other machine learning algorithms. For example, GPT with Support Vector Regression (SVR), or BERT with SVR.

Taking BERT and SVR model training for example, Table (1) shows the relationship between sub-periods and historical electricity consumption. The training data is the text content of the historical electricity consumption. The content of Table (1) may serve as training data for parameter adaptation of the extraction model based on BERT and SVR, and be used to perform model parameter assessment, that is, be used to train model parameters.

TABLE 1

| | | | Time | Corresponding Text of | |
|---|---|---|---|---|---|
| | | | Period | Historical Bills from | Electricity |
| Year | Month | Region | Type | Electricity Supply Bureau | Consumption |
| 2023 | 2 | C | Billed | From the provided customer | 1888 |
| | | | semi-peak | numbers and bill text thereof | |
| | | | kWh | from Region C, the summary | |
| | | | | content related to “billed | |
| | | | | semi-peak kWh” is extracted: | |
| | | | | Semi-peak (non-summer | |
| | | | | months) demand: 1888 | |
| 2023 | 2 | C | Transferred | From the provided customer | 3000 |
| | | | semi-peak | numbers and bill text thereof | |
| | | | kWh | from Region C, the summary | |
| | | | | content related to | |
| | | | | “transferred semi-peak | |
| | | | | kWh” is extracted: Semi- | |
| | | | | peak kWh: 3000 | |
| . . . | . . . | . . . | . . . | . . . | . . . |

The target extraction module 132 may extract the historical electricity consumption from the electricity use data by inputting the electricity use data into the extraction model (Step S320). As described in Step S310, the extraction model is a machine learning model trained by a machine learning algorithm and knowing the correlation between the electricity use data and the electricity consumption. Therefore, by inputting the electricity use data into the proportion model, the extraction model can output the historical electricity consumption corresponding to the electricity use data, that is, extract the historical electricity consumption from the electricity use data.

For example, the following is the historical electricity consumption of the target energy (taking transferred and billed renewable energy for example) obtained after inputting the electricity use data in text form into the extraction model:

TABLE 2

| | | | | Corresponding Text of | |
|---|---|---|---|---|---|
| | | | Time Period | Historical Bills from | Electricity |
| Year | Month | Region | Type | Electricity Supply Bureau | Consumption |
| 2023 | 2 | A | Billed | From the provided customer | 1500 |
| | | | semi-peak | numbers and bill text thereof | |
| | | | kWh | from Region A, the summary | |
| | | | | content related to “billed | |
| | | | | semi-peak kWh” is extracted: | |
| | | | | Semi-peak electricity | |
| | | | | consumption: 1500 | |
| 2023 | 2 | B | Billed | From the provided customer | 2000 |
| | | | semi-peak | numbers and bill text thereof | |
| | | | kWh | from Region B, the summary | |
| | | | | content related to “billed | |
| | | | | semi-peak kWh” is extracted: | |
| | | | | Semi-peak demand: 2000 | |
| 2023 | 2 | C | Transferred | From the provided customer | 3000 |
| | | | semi-peak | numbers and bill text thereof | |
| | | | kWh | from Region C, the summary | |
| | | | | content related to “transferred | |
| | | | | semi-peak kWh” is extracted: | |
| | | | | Transferred semi-peak kWh: | |
| | | | | 3000 | |

In another embodiment, the processor 13 may receive a trained extraction model through the input device 11. That is, the historical electricity consumption corresponding to the electricity use data is determined through the extraction model trained by other devices. In another embodiment, the processor 13 may receive user operations through the input device 11, and through the user operations, the historical electricity consumption in one or more sub-periods is keyed in.

In an embodiment, the total amount estimation module 131 may determine the future total electricity according to the time series corresponding to the electricity consumption records of all energy. The electricity consumption record includes the electricity consumption of all these energy in past periods, that is, the electricity consumption of all energy in one or more past time intervals before the current time point. The time series is a sequence composed of multiple sub-intervals, and includes the electricity consumptions corresponding to the sub-intervals. In an embodiment, the total amount estimation module 131 may receive usage data from the electricity consumption record through the input device 11, and obtain the numerical values or content of historical usage from the usage data.

For example, Table (3) shows the electricity consumptions in various time periods in multiple regions from 2020 to 2023 (i.e., electricity consumptions in past periods):

TABLE 3

| | | | Peak Time | Semi-Peak | Off-Peak |
|---|---|---|---|---|---|
| | | | Period | Time Period | Time Period |
| | | | Electricity | Electricity | Electricity |
| | | | Consumption | Consumption | Consumption |
| Year | Month | Region | (kWh) | (kWh) | (kWh) |
| 2020 | 1 | A | 10000 | 12000 | 5000 |
| 2020 | 2 | A | 11000 | 12340 | 4830 |
| 2020 | 3 | A | 10500 | 12040 | 4500 |
| . . . | | . . . | . . . | . . . | . . . |
| 2023 | 10 | C | 20000 | 25000 | 24000 |
| 2023 | 11 | C | 23000 | 23500 | 23000 |
| 2023 | 12 | C | 21000 | 22500 | 22000 |

On the other hand, the future total electricity is the estimated amount of all energy used in future periods. That is, the electricity consumption (or called total electricity consumption) of all energy in one or more future time periods after the current time.

FIG. 4 is a flowchart illustrating the determination of future total electricity according to an embodiment of the disclosure. Referring to FIG. 4, the total amount estimation module 131 may train an electricity assessment model (Step S410). The electricity assessment model is trained based on a time series model. The electricity assessment model is trained to understand the correlation between the time series and the future total electricity. The time series model, for example, may be an autoregressive integrated moving average (ARIMA) model, recurrent neural network (RNN), long short-term memory (LSTM), or other model related to time. The time series model analyzes labeled samples (for example, determined total electricity in multiple past periods in sequence) to establish the correlation between the electricity consumption record (i.e., the input of the model) and the future total electricity (i.e., the output of the model). The electricity assessment model is the model constructed after learning, and may be used to infer from data to be assessed (for example, the electricity consumption in the past period to be assessed) to predict the future total electricity corresponding to the electricity consumption in the past period.

For example, Table (4) shows the electricity consumptions of all energy in multiple past periods:

TABLE 4

| | | | Peak Time | Semi-Peak | Off-Peak |
|---|---|---|---|---|---|
| | | | Period | Time Period | Time Period |
| | | | Electricity | Electricity | Electricity |
| | | | Consumption | Consumption | Consumption |
| Year | Month | Region | (kWh) | (kWh) | (kWh) |
| 2020 | 1 | A | 10000 | 12000 | 5000 |
| 2020 | 2 | A | 11000 | 12340 | 4830 |
| 2020 | 3 | A | 10500 | 12040 | 4500 |
| . . . | | . . . | . . . | . . . | . . . |
| 2023 | 10 | C | 20000 | 25000 | 24000 |
| 2023 | 11 | C | 23000 | 23500 | 23000 |
| 2023 | 12 | C | 21000 | 22500 | 22000 |

The total amount estimation module 131 utilizes the correlation between the electricity consumptions across several months before and after each time period in each region. For example, a total electricity consumption in a single time period in the current month (\hat{X}ₜ), a total electricity consumption in a single time period in the previous month (\hat{X}ₜ₋₁), a total electricity consumption in a single time period two months ago (\hat{X}ₜ₋₂), and a total electricity consumption in a single time period three months ago (\hat{X}ₜ₋₃) are variables X. Accordingly, a time series is defined as: \hat{X}ₜ_{_{site A}}=a₁\hat{X}ₜ₋₁+a₂\hat{X}ₜ₋₂+a₃\hat{X}ₜ₋₃, wherein \hat{X}ₜ_{_{site A}} is the future total electricity in Region A, and a₁, a₂, and a₃ are coefficients. A time series model ARIMA (3,0,0) is used for example. The electricity consumption record may be used to train the electricity assessment model.

Regarding the coefficients a₁, a₂, and a₃, in terms of the semi-peak total electricity consumption in Region C, the coefficient a₁ may be, for example, 0.85. The coefficient a₂ may be, for example, −0.0372. The coefficient a₃ may be, for example, 0.15. According to the example values, inputting the semi-peak total electricity in January 2024 into the time series formula yields: the semi-peak total electricity consumption in January 2024=22000 (=22500*0.85+23500*(−0.0372)+25000*0.15).

The total amount estimation module 131 may determine the future total electricity of all energy by inputting the electricity consumption records of all energy into the electricity assessment model (Step S420). As described in Step S410, the electricity assessment model is a machine learning model trained based on a time series model, and knows the correlation between the total electricity in multiple sequential past periods. Therefore, by inputting the electricity consumption records of all energy into the electricity assessment model, the electricity assessment model output the future total electricity corresponding to the electricity consumption records.

For example, Table (5) shows the electricity consumptions of all energy to be assessed in Region C during past periods:

TABLE 5

| Year | Month | \hat{X}ₜ₋₁ | \hat{X}ₜ₋₂ | \hat{X}ₜ₋₃ |
|---|---|---|---|---|
| 2024 | 1 | 22500 | 23500 | 25000 |

Assuming the future total electricity is the semi-peak total electricity consumption in January 2024, to assess the semi-peak total electricity consumption in January 2024, the input of the model may be defined as the electricity consumptions from November 2023 to December 2023 (substituted into \hat{X}ₜ₋₁, \hat{X}ₜ₋₂, \hat{X}ₜ₋₃ respectively), and the output as the estimated value in January 2024 (i.e., the future total electricity).
The total amount estimation module 131 sequentially inputs the electricity consumption records of multiple electricity consumption time periods in each month in each region into the electricity assessment model to determine the future total electricity:

TABLE 6

| | | | Peak | Semi-Peak | Off-Peak |
|---|---|---|---|---|---|
| | | | Electricity | Electricity | Electricity |
| | | | Consumption | Consumption | Consumption |
| Year | Month | Region | (kWh) | (kWh) | (kWh) |
| 2024 | 1 | C | 21000 | 22000 | 22000 |
| 2024 | 2 | C | 22000 | 23000 | 24000 |
| 2024 | 3 | C | 20000 | 25500 | 23500 |

Referring to FIG. 2, the processor 13 determines the electricity distribution corresponding to the electricity consumption in one or more sub-periods through the proportion determination module 133 (Step S220). Specifically, the electricity distribution is the distribution of estimated electricity consumptions in multiple sub-periods formed by using the electricity consumption of a certain sub-period as the standard. Assuming that the electricity consumption of the target energy in any sub-period is a random variable, and the electricity consumptions of the target energy in multiple consecutive sub-periods approaches a certain probability distribution, the proportion determination module 133 may use this probability distribution to simulate or fit the sum of electricity consumptions in multiple sub-periods. The method of setting the standard may be setting a certain sub-period as the mean, median, or other statistical value of the probability distribution. The electricity distribution may be used to determine the estimated sum, and the estimated sum is the sum of the estimated electricity consumptions in multiple sub-periods under the electricity distribution.

In an embodiment, the proportion determination module 133 may determine the type of probability distribution of the target energy. Different types of target energy may have different distributions of electricity consumption over multiple consecutive sub-periods. In an embodiment, the proportion determination module 133 may determine that the target energy is solar energy, and that the type of the probability distribution of the solar energy is a normal distribution. In another embodiment, the proportion determination module 133 may determine that the target energy is wind energy, and that the type of probability distribution is a uniform distribution. In other embodiments, the probability distribution may also be of other types.

The sub-periods include a first period. The proportion determination module 133 may generate the electricity distribution by using the electricity consumption in the first period as the standard for the probability distribution. Specifically, a certain sub-period is used to normalize other sub-periods. For example, the first period is a 12 o'clock time period with the normalized value being defined as zero, and the normalized values from 0 to 24 o'clock are from −3 to 3. That is, normalized time=(sub-period-12)/4. Taking 12 o'clock for example, the normalized 12 o'clock time period=0 (i.e., (12−12)/4). An assumption is made that the electricity consumption of the target energy in multiple sub-periods is as shown in Table (7), and the normalized sub-periods are as shown in Table (8):

TABLE 7

| | Sub-Period/Time Period (o'clock) | | | | | | | |
|---|---|---|---|---|---|---|---|---|
| | . . . | 8 | 9 | 10 | 11 | 12 | 13 | . . . |
| Secondary Electricity | . . . | 180 | 200 | 190 | 110 | 100 | 110 | . . . |
| Consumption (kWh) | | | | | | | | |
| (Exemplified with | | | | | | | | |
| February) | | | | | | | | |

TABLE 8

| | | | |
|---|---|---|---|
| Sub-Period/Time | 11 | 12 | 13 |
| Period (o'clock) | | | |
| Normalized Time | −0.25 | 0 | 0.25 |
| Secondary | 110 | 100 | 110 |
| Electricity | | | |
| Consumption | | | |
| (kWh) | | | |

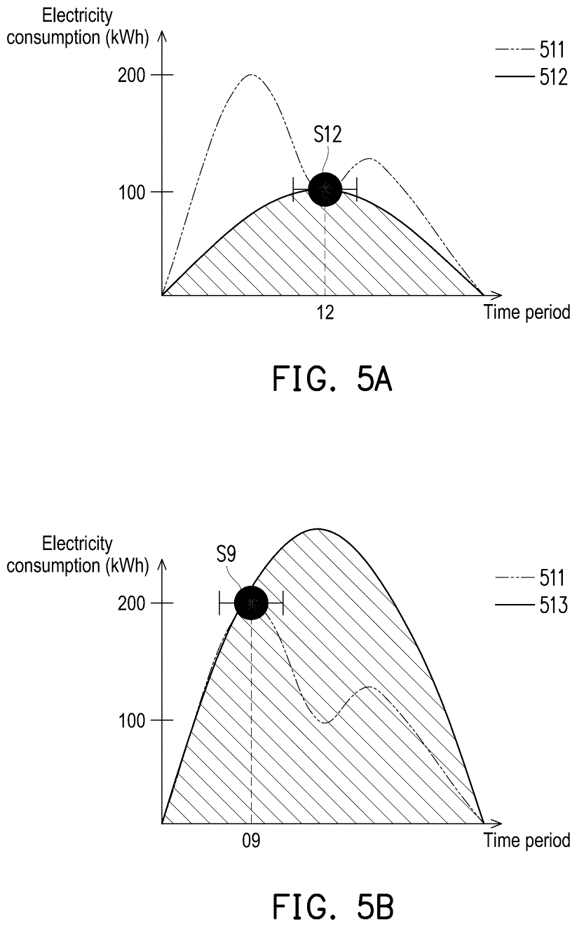

The electricity consumption in the first period equals the estimated electricity consumption corresponding to the first period in the electricity distribution. FIG. 5A and FIG. 5B are schematic diagrams illustrating a historical electricity consumption 511 and an electricity distribution 512 according to an embodiment of the disclosure. Referring to FIG. 5A, the electricity distribution 512 is exemplified as a normal distribution (e.g., for solar energy), a standard S12 is 12 o'clock (i.e., as the aforementioned first period), and the time period of the standard S12 equals the mean of the electricity distribution 512. The curve of the electricity distribution 512 passes through the standard S12, and the curve of the electricity distribution 512 overlaps with the curve of the historical electricity consumption 511 at the standard S12. The cumulative probability between an interval of −0.25 to 0.25 is 0.20. That is, if the probability of multiple sub-periods (from 0 to 23 o'clock) is 1, then the cumulative probability from 11 to 13 o'clock is 0.20, and the estimated sum can be deduced from Table (8) as 1600 (kWh) (i.e., (110+100+110)/0.20), which is the area between the curve corresponding to the electricity distribution 512 and the horizontal axis (the shaded part).

Referring to FIG. 5B, alternatively, an assumption is made that the first period is the 9 o'clock time period, and the normalized sub-periods are as shown in Table (9):

TABLE 9

| | | | |
|---|---|---|---|
| Sub-Period/Time | 8 | 9 | 10 |
| Period (o'clock) | | | |
| Normalized Time | −1 | −0.75 | −0.5 |
| Secondary Electricity | 180 | 200 | 190 |
| Consumption (kWh) | | | |

An electricity distribution 513 is exemplified as a normal distribution. A standard S9 is 9 o'clock (i.e., as the aforementioned first period), and the time period of the standard S9 equals the mean of the electricity distribution 513. The curve of the electricity distribution 513 passes through the standard S9, and the curve of the electricity distribution 513 overlaps with the curve of the historical electricity consumption 511 at the standard S9. The cumulative probability between an interval of −0.1 to 0.5 is 0.15, and the estimated sum can be deduced from Table (9) as 3800 (kWh) (i.e., (180+200+190)/0.15), which is the area between the curve corresponding to the electricity distribution 513 and the horizontal axis (the shaded part).

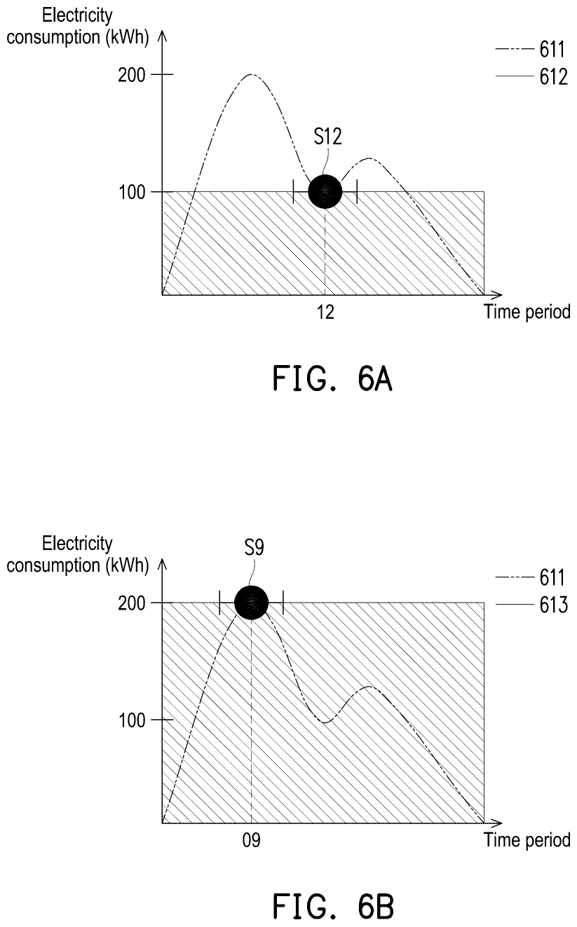

FIG. 6A and FIG. 6B are schematic diagrams illustrating a historical electricity consumption 611 and electricity distributions 612 and 613 according to an embodiment of the disclosure. Referring to FIG. 6A, the electricity distribution 612 is exemplified as a uniform distribution (e.g., for wind energy), and the standard S12 is 12 o'clock (i.e., as the aforementioned first period). The straight line of the electricity distribution 612 passes through the standard S12, and the straight line of the electricity distribution 612 overlaps with the curve of the historical electricity consumption 611 at the standard S12. The sub-periods regarding the historical electricity consumption 611 may be normalized (for example, normalized time=(sub-period-0)/24), resulting in Table (10):

TABLE 10

| | | | |
|---|---|---|---|
| Sub-Period/Time | 11 | 12 | 13 |
| Period (o'clock) | | | |
| Normalized Time | 0.46 | 0.50 | 0.54 |
| Actual Electricity | 110 | 100 | 110 |
| Consumption | | | |

The cumulative probability between an interval of 0.46 to 0.54 is 0.08. That is, if the probability of multiple sub-periods (from 0 to 23 o'clock) is 1, then the cumulative probability from 11 to 13 o'clock is 0.08, and the estimated sum can be deduced from Table (10) as 4000 (kWh) (i.e., (110+100+110)/0.08), which is the area between the straight line corresponding to the electricity distribution 612 and the horizontal axis (the shaded part).

Referring to FIG. 6B, the electricity distribution 613 is exemplified as a uniform distribution, and the standard S9 is 9 o'clock (i.e., as the aforementioned first period). The straight line of the electricity distribution 613 passes through the standard S9, and the straight line of the electricity distribution 613 overlaps with the curve of the historical electricity consumption 611 at the standard S9. The sub-periods regarding the historical electricity consumption 611 may be normalized (for example, normalized time=(sub-period-0)/24), resulting in Table (11):

TABLE 11

| | | | |
|---|---|---|---|
| Sub-Period/Time | 8 | 9 | 10 |
| Period (o'clock) | | | |
| Normalized Time | 0.33 | 0.38 | 0.41 |
| Secondary Electricity | 180 | 200 | 190 |
| Consumption (kWh) | | | |

The cumulative probability between an interval of 0.33 to 0.41 is 0.08. That is, if the probability of multiple sub-periods (from 0 to 23 o'clock) is 1, then the cumulative probability from 11 to 13 o'clock is 0.08, and the estimated sum can be deduced from Table (11) as 7125 (kWh) (i.e., (180+200+190)/0.08), which is the area between the straight line corresponding to the electricity distribution 613 and the horizontal axis (the shaded part).

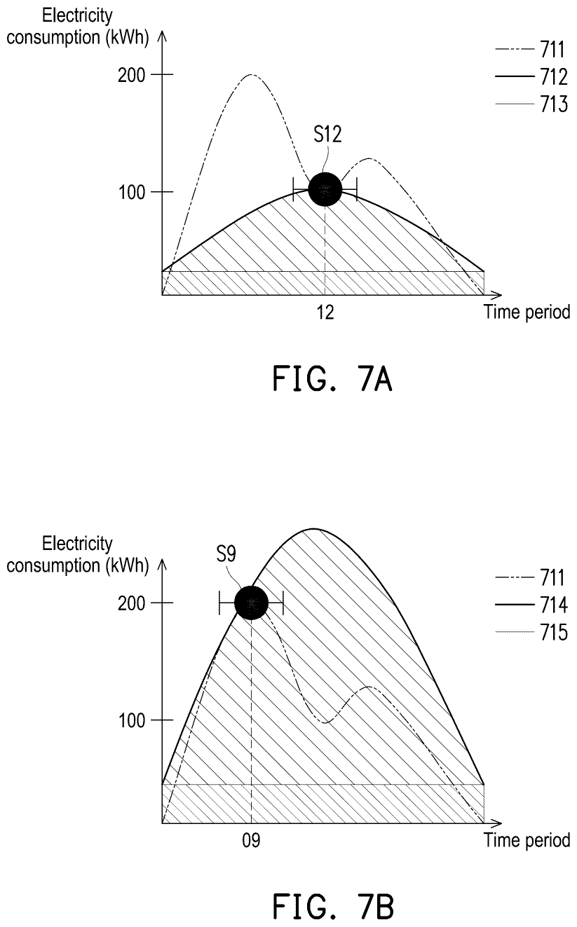

FIG. 7A and FIG. 7B are schematic diagrams illustrating a historical electricity consumption 711 and electricity distributions 712 to 715 according to an embodiment of the disclosure. Referring to FIG. 7A, an assumption is made that the target energy includes 80% solar energy and 20% wind energy. The electricity distribution 712 is exemplified as a normal distribution, and the electricity distribution 713 is exemplified as a uniform distribution, with the standard S12 being 12 o'clock (i.e., as the aforementioned first period). The curve corresponding to the sum of the electricity distributions 712 and 713 passes through the standard S12, and the curve corresponding to the sum of the electricity distributions 712 and 713 overlaps with the curve of the historical electricity consumption 711 at the standard S12. The historical electricity consumption 711 is shown in Table (12):

TABLE 12

| Sub-Period/Time Period | 11 | 12 | 13 |
|---|---|---|---|
| (o'clock) | | | |
| Secondary Electricity | 110 | 100 | 110 |
| Consumption (kWh) | | | |
| Cumulative Probability of | 0.2 | | |
| Solar Energy | | | |
| Cumulative Probability of | 0.08 | | |
| Wind Energy | | | |

The mixed cumulative probability between 11 to 13 o'clock is 0.2*80%+0.08*20%=0.176. That is, if the probability of multiple sub-periods (from 0 to 23 o'clock) is 1, then the cumulative probability from 11 to 13 o'clock is 0.176, and the estimated sum can be deduced from Table (12) as 1818 (kWh) (i.e., (110+100+110)/0.176), which is the area between the curve corresponding to the sum of the electricity distributions 712 and 713 and the horizontal axis (the shaded part).

Referring to FIG. 7B, an assumption is made that the target energy includes 80% solar energy and 20% wind energy. The electricity distribution 714 is exemplified as a normal distribution, and the electricity distribution 715 is exemplified as a uniform distribution, with the standard S9 being 9 o'clock (i.e., as the aforementioned first period). The curve corresponding to the sum of the electricity distributions 714 and 715 passes through the standard S9, and the curve corresponding to the sum of the electricity distributions 714 and 715 overlaps with the curve of the historical electricity consumption 711 at the standard S9. The historical electricity consumption 711 is shown in Table (13):

TABLE 13

| Sub-Period/Time Period | 8 | 9 | 10 |
|---|---|---|---|
| (o'clock) | | | |
| Secondary Electricity | 180 | 200 | 190 |
| Consumption (kWh) | | | |
| Cumulative Probability of | 0.15 | | |
| Solar Energy | | | |
| Cumulative Probability of | 0.08 | | |
| Wind Energy | | | |

The mixed cumulative probability between 11 to 13 o'clock is 0.15*80%+0.08*20%=0.136. That is, if the probability of multiple sub-periods (from 0 to 23 o'clock) is 1, then the cumulative probability from 8 to 10 o'clock is 0.136, and the estimated sum can be deduced from Table (13) as 4191 (kWh) (i.e., (180+200+190)/0.136), which is the area between the curve corresponding to the sum of the electricity distributions 714 and 715 and the horizontal axis (the shaded part).

It is noted that the values and intervals in Tables (7) to (13) are only used as examples for description, and changes may be applied by users according to actual requirements.

Referring to FIG. 2, the proportion determination module 133 determines a recommended proportion of the target energy according to a usage difference between the historical electricity consumption and the electricity distribution (Step S230). Specifically, the recommended proportion is a proportion of the recommended amount of target energy to the electricity consumption of all energy. Based on criteria or regulations, the target energy may not account for all electricity consumptions of all energy. However, the recommended amount of the target energy should still meet the actual demand to avoid waste.

The usage difference is a difference between the historical electricity consumption and the estimated sum (i.e., a difference value obtained by subtracting the estimated sum from the historical electricity consumption), and the estimated sum is a sum of the estimated electricity consumptions in multiple sub-periods under the electricity distribution. As described above, the electricity distribution is a probability distribution that takes a certain sub-period as the standard (i.e., the aforementioned first period) and generates estimated electricity consumptions for other sub-periods accordingly. Each point on the curve or line of the electricity distribution corresponds to the estimated electricity consumption of the corresponding sub-period. The smaller the usage difference, the closer the estimated sum is to the historical electricity consumption, and the corresponding electricity distribution may be close to the actual electricity consumption of the target energy. Conversely, the larger the usage difference, the further the estimated sum is from the historical electricity consumption, and the corresponding electricity distribution may not match the actual electricity consumption of the target energy.

In an embodiment, the sub-periods include a second period. The proportion determination module 133 may determine that a usage difference corresponding to the second period is the smallest among the usage differences corresponding to the sub-periods. Specifically, the proportion determination module 133 may obtain the electricity distributions with each of the sub-periods as the standard, respectively determine the estimated sums corresponding to the electricity distributions, and respectively determine the usage differences between the estimated sums and the historical electricity consumption. Then, the proportion determination module 133 obtains the smallest one from the usage differences.

The proportion determination module 133 may determine the recommended proportion according to the estimated sum corresponding to the second period and the electricity consumption records of all energy. The estimated sum is the recommended amount of target energy in multiple sub-periods. The electricity consumption records of all energy include the electricity consumptions of all energy in multiple sub-periods. The proportion of the estimated sum to the sum of the electricity consumptions of all energy in the sub-periods is the recommended proportion.

In an embodiment, the proportion determination module 133 may respectively determine multiple difference rates between the estimated sums corresponding to the sub-periods and the electricity consumption records of all energy. Specifically, the difference rate is defined as (estimated sum-sum of electricity consumptions of all energy in multiple sub-periods)/sum of electricity consumptions of all energy in multiple sub-periods %. For example, summing up hourly electricity consumptions, a monthly electricity consumption is obtained, a value of which being 2600 kWh (as the sum of electricity consumptions of all energy in multiple sub-periods), and the difference rate is as follows:

TABLE 14

| | | | | | |
|---|---|---|---|---|---|
| Standard (point) | 9 | 12 | 10 | 14 | . . . |
| Estimated Sum of | 3800 | 1600 | 2600 | 2100 | . . . |
| Target Energy (kWh) | | | | | |
| Sum of Electricity | 2600 | 2600 | 2600 | 2600 | . . . |
| Consumptions of All | | | | | |
| Energy in Sub-Periods | | | | | |
| (kWh) | | | | | |
| Difference Rate | 46% | −38% | 0% | −19% | . . . |

Taking 9 o'clock for example, the difference rate is 46% (i.e., (3800−2600)/2600)%, and descriptions of the rest will not be repeated.

The proportion determination module 133 may select the estimated sum corresponding to the second period from the sub-periods according to the difference rates. Considering that the estimated sum exceeds the actual total electricity consumption, which results in unused energy, the second period may be selected based on the difference rate. In an embodiment, the proportion determination module 133 may determine that the difference rate corresponding to the second period is equal to or less than a difference rate threshold, with the difference rate threshold being zero. Taking Table (14) for example, the difference rates corresponding to 10 o'clock, 12 o'clock, and 14 o'clock are less than or equal to the difference rate threshold, and the estimated sum for 9 o'clock may be excluded or ignored.

In addition, the estimated sum corresponding to the second period is used to determine the recommended proportion. Taking Table (14) for example, the usage differences corresponding to 10 o'clock, 12 o'clock, and 14 o'clock are:

TABLE 15

| | | | |
|---|---|---|---|
| Standard (point) | 10 | 12 | 14 |
| Estimated Sum (kWh) | 2600 | 1600 | 2100 |
| Historical Electricity | 1700 | 1700 | 1700 |
| Consumption (kWh) | | | |
| Usage Difference (kWh) | 900 | 100 | 400 |

The usage difference corresponding to 12 o'clock is the minimum value, meaning that the time period of 12 o'clock may serve as the second period. The proportion of the estimated sum to the sum of the electricity consumptions of all energy in the sub-periods is the recommended proportion: 62% (=1600/2600).

Taking FIG. 6A and FIG. 6B as another example, the difference rates are as follows:

TABLE 16

| | | | |
|---|---|---|---|
| Standard (point) | 9 | 12 | . . . |
| Estimated Sum of | 7125 | 4000 | . . . |
| Target Energy (kWh) | | | |
| Sum of Electricity | 4200 | 4200 | . . . |
| Consumption of All | | | |
| Energy in Sub-Periods | | | |
| (kWh) | | | |
| Difference Rate | 70% | −4.8% | . . . |

Taking Table (16) for example, the estimated sum for 9 o'clock is excluded, and the usage differences corresponding to 10 o'clock, 12 o'clock, and 13 o'clock are:

TABLE 17

| | | | |
|---|---|---|---|
| Standard (point) | 10 | 12 | 13 |
| Estimated Sum (kWh) | 4100 | 4000 | 4050 |
| Historical Electricity | 3700 | 3700 | 3700 |
| Consumption (kWh) | | | |
| Usage Difference (kWh) | 400 | 300 | 350 |

The usage difference corresponding to 12 o'clock is the minimum value, meaning that the time period of 12 o'clock may serve as the second period. The proportion of the estimated sum to the sum of the electricity consumptions of all energy in the sub-periods is the recommended proportion: 95% (=4000/4200).

Taking FIG. 7A and FIG. 7B as another example, the difference rates are as follows:

TABLE 18

| | | | |
|---|---|---|---|
| Standard (point) | 9 | 12 | . . . |
| Estimated Sum of | 4191 | 1818 | . . . |
| Target Energy (kWh) | | | |
| Sum of Electricity | 3000 | 3000 | . . . |
| Consumptions of All | | | |
| Energy in Sub-Periods | | | |
| (kWh) | | | |
| Difference Rate | 40% | −39% | . . . |

Taking Table (18) for example, the estimated sum for 9 o'clock is excluded, and the usage differences corresponding to 10 o'clock, 12 o'clock, and 13 o'clock are:

TABLE 19

| | | | |
|---|---|---|---|
| Standard (point) | 10 | 12 | 13 |
| Estimated Sum (kWh) | 2000 | 1818 | 2050 |
| Historical Electricity | 2900 | 2900 | 2900 |
| Consumption (kWh) | | | |
| Usage Difference (kWh) | 900 | 1082 | 850 |

The usage difference corresponding to 13 o'clock is the minimum value, meaning that the time period of 13 o'clock may serve as the second period. The proportion of the estimated sum to the sum of the electricity consumptions of all energy in the sub-periods is the recommended proportion: 68% (=2050/3000).

In an embodiment, the processor 13 may, through the adjustment module 134, determine the construction amount of the target energy according to a future electricity consumption. Specifically, the future electricity consumption is a product of the future total electricity of all energy and the recommended proportion. The future total electricity is the estimated amount of all energy used in a future period. References may be made to the above descriptions for the introduction of the future total electricity, and the descriptions will not be repeated here.

The construction amount is a usage of elements of the power generation equipment for the target energy. The elements of the power generation equipment may be solar panels or wind power generators, but are not limited thereto. The usage may be measured by quantity, size, or electrical features. For example, an area of solar panels.

For example, Table (20) is a comparison table of future total electricity, recommended proportions, and future electricity consumptions:

TABLE 20

| Month | 01 | . . . | 12 |
|---|---|---|---|
| Future Total Electricity - | 2,000 | . . . | 1,800 |
| Estimated Semi-Peak | | | |
| Electricity Consumption | | | |
| (kWh) | | | |
| Future Total Electricity - | 1,000 | . . . | 900 |
| Estimated Saturday | | | |
| Semi-Peak Electricity | | | |
| Consumption (kWh) | | | |
| Future Total Electricity - | 2,600 | . . . | 2,300 |
| Estimated Off-Peak | | | |
| Electricity Consumption | | | |
| (kWh) | | | |
| Future Total Electricity - | 5,600 | . . . | 5,100 |
| Estimated Monthly | | | |
| Total Electricity | | | |
| Consumption (kWh) | | | |
| Recommended | 58% | . . . | 62% |
| Proportion | | | |
| (According to the same | | | |
| historical month) | | | |
| Future Electricity | 3,248 | . . . | 3,162 |
| Consumption | | | |

The estimated monthly total electricity=estimated electricity consumption during semi-peak hours+estimated electricity consumption during Saturday semi-peak hours+estimated electricity consumption during off-peak hours. The future electricity consumption of the target energy=estimated monthly total electricity*recommended proportion. For January, the future electricity consumption of the target energy is 3,248 (=5,600*58%). In some applications, the recommended proportion may be affected by seasons.

Taking solar panels as an example of elements of power generation equipment, relevant factors to be considered include: total number of days per month, hours of sunlight, and the area in ping required for unit power generation of solar panels. The maximum future electricity consumption is selected to assess the maximum area required for power generation establishment. Assuming that the maximum future electricity consumption falls in January, the maximum area required for power generation establishment is as follows:

TABLE 21

| Month | 01 |
|---|---|
| Future Electricity Consumption of Target | 3,248 |
| Energy (kWh) | |
| Total Days per Month (days) | 31 |
| Hours of Sunlight | 4 |
| Installation Capacity (KW) | 26.2 |
| (Estimated monthly transfer | |
| amount/maximum total days in a | |
| month/hours of sunlight) | |
| Area Required for Establishment (ping) | 52.4 |
| (Installation capacity *area in ping required | |
| for solar panel unit power generation (=2)) | |

This represents that the maximum area required for establishment is 52.4 (pings). The area in ping required for unit power generation of solar panels is based on a basic unit of 2 (pings).

The maximum area required for establishment may be used to determine the usage of elements of power generation equipment. For example, in a scenario 1, an area for establishing power generation equipment is 45 pings. 45 pings have been used for establishment. The maximum area required for establishment is greater than the area available for establishing power generation equipment, which indicates the need to sign an agreement with suppliers to purchase external renewable energy. The currently installed solar energy capacity is 2,790 (kWh) (=45/2*31*4). For January, it is required to sign an agreement with suppliers for 458 kWh (=3,248−2,790). The same calculation may be applied for other months.

In a scenario 2, an area available for establishing power generation equipment is 60 pings. 45 pings have been used for establishment. The maximum area required for establishment is less than or equal to the area available for establishing power generation equipment, which indicates the need for additional power generation equipment areas. The currently installed solar energy expansion capacity is 7.4 (pings) (=52.4−45). Considering that an area of a solar panel is 2 (pings), 4 (7.4/2≈4) additional solar panels are required.

The above is a recommended plan for the usage of solar panels, which may be similarly applied to other energy. For example, if the power generation equipment is a fan power generation equipment, which elements are fans, whether the required increase in electricity is higher than the capacity of installing a single equipment needs to be assessed. If the required increase in electricity is greater than the capacity of installing a single equipment, it may be recommended to expand the fan power generation equipment. If the required increase in electricity is not greater than the capacity of installing a single equipment, supplement with other renewable energy is required.

In an embodiment, the adjustment module 134 may determine a usage schedule of the power generation equipment for the target energy according to the future electricity consumption. As described above, the future electricity consumption is the product of the future total electricity of all energy and the recommended proportion. The usage schedule records the functioning, halt, stop, sleep, or execution of specific operations of the power generation equipment in specific time periods. For example, if the future electricity consumption only accounts for 80% of the power generation of the power generation equipment under full-time operation, in the usage schedule, the power generation equipment may function 80% of the time and sleep 20% of the time.

Next, the adjustment module 134 may turn off or halt the power generation equipment for the target energy according to the usage schedule. If (all or a part of the functions of) the power generation equipment for the target energy is turned off or halted, the power generation is zero or at the lower limit of power generation (adjusted according to application requirements), and energy may be saved accordingly.

In summary, the embodiments of the disclosure include (but are not limited to) the following characteristics. First, electricity consumption characteristics across multiple periods are integrated, establishing relationships between electricity consumption in multiple sub-periods of a past period to provide future total electricity. Second, applications may be made to various types of renewable energy, such as solar energy, wind energy, biomass energy, etc. Third, different probability distributions may be used for fitting based on the features of different types of power generation to assess the recommended proportion. Finally, the statistical limitations of transfer may be broken through. Even with the limitation of the bills not being subdivided to hourly granularity, proper recommended proportions can still be provided to determine the recommended amount of target energy as a strategic reference basis. Therefore, for each plant site, assistance in assessment and adjustment may be provided based on the recommended amount and the current status of self-built energy for power generation, which may even serve as bases for contracting with suppliers, be used for expansion planning or controlling the operation of power generation equipment.

Although the disclosure has been described with reference to the above embodiments, they are not intended to limit the disclosure. It will be apparent to one of ordinary skill in the art that modifications to the described embodiments may be made without departing from the spirit and the scope of the disclosure. Accordingly, the scope of the disclosure will be defined by the attached claims and their equivalents and not by the above detailed descriptions.

What is claimed is:

1. An energy allocation method, adapted to be implemented by a processor, the energy allocation method comprising:
obtaining a historical electricity consumption of a target energy, wherein the historical electricity consumption is a statistical amount of the target energy used in a past period, the past period comprising a plurality of sub-periods, and the historical electricity consumption comprising a plurality of secondary electricity consumptions in the plurality of sub-periods;
determining an electricity distribution of the secondary electricity consumption corresponding to one of the plurality of sub-periods, wherein the electricity distribution is a distribution of a plurality of estimated electricity consumptions in the plurality of sub-periods formed based on the secondary electricity consumption in the sub-period; and
determining a recommended proportion of the target energy according to a usage difference between the historical electricity consumption and the electricity distribution, wherein the usage difference is a difference between the historical electricity consumption and an estimated sum, the estimated sum is a sum of the plurality of estimated electricity consumptions in the plurality of sub-periods under the electricity distribution, and the recommended proportion is a proportion of a recommended amount of the target energy to an electricity consumption of all energy.

2. The energy allocation method as claimed in claim 1, further comprising:
determining a construction amount of the target energy according to a future electricity consumption, wherein the future electricity consumption is a product of a future total electricity of the all energy and the recommended proportion, the construction amount is an element usage of a power generation equipment for the target energy, and the future total electricity is an estimated amount of the all energy used in a future period.

3. The energy allocation method as claimed in claim 1, wherein the plurality of sub-periods comprise a first period, and determining the electricity distribution corresponding to the secondary electricity consumption in the one of the plurality of sub-periods comprises:
determining a type of a probability distribution of the target energy; and
generating the electricity distribution by using the secondary electricity consumption of the first period as a standard of the probability distribution, wherein the secondary electricity consumption of the first period equals an estimated electricity consumption corresponding to the first period in the electricity distribution.

4. The energy allocation method as claimed in claim 3, wherein determining the type of the probability distribution of the target energy comprises:
determining the target energy as a solar energy, and determining the type of the probability distribution as a normal distribution; or
determining the target energy as a wind energy, and determining the type of the probability distribution as a uniform distribution.

5. The energy allocation method as claimed in claim 1, wherein the plurality of sub-periods comprise a second period, and determining the recommended proportion of the target energy according to the usage difference between the historical electricity consumption and the electricity distribution comprises:
determining the usage difference corresponding to the second period as a smallest one among the plurality of usage differences corresponding to the plurality of sub-periods; and
determining the recommended proportion according to the estimated sum corresponding to the second period and an electricity consumption record of the all energy, wherein the electricity consumption record of the all energy comprises the electricity consumption of the all energy in the plurality of sub-periods.

6. The energy allocation method as claimed in claim 1, wherein determining the recommended proportion of the target energy according to the usage difference between the historical electricity consumption and the electricity distribution comprises:
determining a plurality of difference rates between the estimated sum corresponding to the plurality of sub-periods and an electricity consumption record of the all energy, respectively; and
selecting the estimated sum corresponding to a second period from the plurality of sub-periods according to the plurality of difference rates, wherein the estimated sum corresponding to the second period is used to determine the recommended proportion.

7. The energy allocation method as claimed in claim 6, wherein selecting the estimated sum corresponding to the second period from the plurality of sub-periods according to the plurality of difference rates comprises:
determining the difference rate corresponding to the second period being equal to or less than a difference rate threshold, wherein the difference rate threshold is zero.

8. The energy allocation method as claimed in claim 2, further comprising:
determining the future total electricity of the all energy by inputting an electricity consumption record of the all energy into an electricity assessment model, wherein the electricity consumption record of the all energy comprises the electricity consumption of the all energy in the past period, and the electricity assessment model is trained based on a time series model.

9. The energy allocation method as claimed in claim 1, wherein obtaining the historical electricity consumption of the target energy comprises:
extracting the historical electricity consumption from an electricity data by inputting the electricity data into an extraction model, wherein the extraction model is trained through a machine learning algorithm.

10. The energy allocation method as claimed in claim 1, further comprising:
determining a usage schedule of a power generation equipment for the target energy according to a future electricity consumption, wherein the future electricity consumption is a product of a future total electricity of the all energy and the recommended proportion; and
turning off or halting the power generation equipment for the target energy according to the usage schedule.

11. A computing apparatus, comprising:
a storage, storing a program code; and
a processor, coupled to the storage, loading the program code and executing:
obtaining a historical electricity consumption of a target energy, wherein the historical electricity consumption is a statistical amount of the target energy used in a past period, the past period comprising a plurality of sub-periods, and the historical electricity consumption comprising a plurality of secondary electricity consumptions in the plurality of sub-periods;
determining an electricity distribution of the secondary electricity consumption corresponding to one of the plurality of sub-periods, wherein the electricity distribution is a distribution of a plurality of estimated electricity consumptions in the plurality of sub-periods formed based on the secondary electricity consumption in the sub-period; and
determining a recommended proportion of the target energy according to a usage difference between the historical electricity consumption and the electricity distribution, wherein the usage difference is a difference between the historical electricity consumption and an estimated sum, the estimated sum is a sum of the plurality of estimated electricity consumptions in the plurality of sub-periods under the electricity distribution, and the recommended proportion is a proportion of a recommended amount of the target energy to an electricity consumption of all energy.

12. The computing apparatus as claimed in claim 11, wherein the processor further executes:
determining a construction amount of the target energy according to a future electricity consumption, wherein the future electricity consumption is a product of a future total electricity of the all energy and the recommended proportion, the construction amount is an element usage of a power generation equipment for the target energy, and the future total electricity is an estimated amount of the all energy used in a future period.

13. The computing apparatus as claimed in claim 11, wherein the plurality of sub-periods comprise a first period, and the processor further executes:
determining a type of a probability distribution of the target energy; and
generating the electricity distribution by using the secondary electricity consumption of the first period as a standard of the probability distribution, wherein the secondary electricity consumption of the first period equals an estimated electricity consumption corresponding to the first period in the electricity distribution.

14. The computing apparatus as claimed in claim 13, wherein the processor further executes:
determining the target energy as a solar energy, and determining the type of the probability distribution as a normal distribution; or
determining the target energy as a wind energy, and determining the type of the probability distribution as a uniform distribution.

15. The computing apparatus as claimed in claim 11, wherein the plurality of sub-periods comprise a second period, and the processor further executes:
determining the usage difference corresponding to the second period as a smallest one among the plurality of usage differences corresponding to the plurality of sub-periods; and
determining the recommended proportion according to the estimated sum corresponding to the second period and an electricity consumption record of the all energy, wherein the electricity consumption record of the all energy comprises the electricity consumption of the all energy in the plurality of sub-periods.

16. The computing apparatus as claimed in claim 11, wherein the processor further executes:
determining a plurality of difference rates between the estimated sum corresponding to the plurality of sub-periods and an electricity consumption record of the all energy, respectively; and
selecting the estimated sum corresponding to a second period from the plurality of sub-periods according to the plurality of difference rates, wherein the estimated sum corresponding to the second period is used to determine the recommended proportion.

17. The computing apparatus as claimed in claim 16, wherein the processor further executes:
determining the difference rate corresponding to the second period being equal to or less than a difference rate threshold, wherein the difference rate threshold is zero.

18. The computing apparatus as claimed in claim 12, wherein the processor further executes:
determining the future total electricity of the all energy by inputting an electricity consumption record of the all energy into an electricity assessment model, wherein the electricity consumption record of the all energy comprises the electricity consumption of the all energy in the past period, and the electricity assessment model is trained based on a time series model.

19. The computing apparatus as claimed in claim 11, wherein the processor further executes:
extracting the historical electricity consumption from an electricity data by inputting the electricity data into an extraction model, wherein the extraction model is trained through a machine learning algorithm.

20. The computing apparatus as claimed in claim 11, wherein the processor further executes:
determining a usage schedule of a power generation equipment for the target energy according to a future electricity consumption, wherein the future electricity consumption is a product of a future total electricity of the all energy and the recommended proportion; and
turning off or halting the power generation equipment for the target energy according to the usage schedule.
